(19) United States
(12) Patent Application Publication
(10) Pub. No.: US 2024/0155740 A1
(43) Pub. Date: May 9, 2024

(54) HEATER STAGE

(71) Applicant: SAMSUNG ELECTRONICS CO., LTD., SUWON-SI (KR)

(72) Inventor: Yoshiaki MORIYA, Yokohama (JP)

(21) Appl. No.: 18/383,077

(22) Filed: Oct. 24, 2023

(30) Foreign Application Priority Data
Nov. 2, 2022 (JP) 2022-176562
Feb. 27, 2023 (KR) 10-2023-0026182

(51) Int. Cl. H05B 3/28

(52) U.S. Cl. CPC H05B 3/283; H02N 13/00

(57) ABSTRACT

A heater stage includes an insulating ceramic substrate including lower and upper substrates, each including a first ceramic, and a heat generating element located between the lower substrate and the upper substrate and including a second ceramic and a second metal carbide. The first ceramic of the insulating ceramic substrate and the second ceramic of the heat generating element include at least one of a metal nitride and a metal oxide, a content of the second ceramic in the heat generating element is greater than a content of the second metal carbide in the heat generating element, the heat generating element has a relative density of 95% or more and a volume resistance value of 1.0 Ω·cm or less at room temperature, and a rate of change of the volume resistance value of the heat generating element with an increase in temperature by 100° C. is 0.1 or less.

### CROSS-REFERENCE TO RELATED APPLICATION

This application is based on and claims priority under 35 U.S.C. § 119 to Japanese Patent Application No. 2022-176562, filed on Nov. 2, 2022, in the Japan Patent Office, and Korean Patent Application No. 10-2023-0026182, filed on Feb. 27, 2023, filed in the Korean Intellectual Property Office, the disclosures of which are incorporated by reference herein in their entirety.

### BACKGROUND

### 1. Field

Embodiments relate to a heater stage, and more particularly, to a heater stage on which a substrate, such as a semiconductor wafer, is mounted.

### 2. Description of the Related Art

In a substrate mounting stage used in a semiconductor manufacturing process, such as dry etching, epitaxial growth, chemical vapor deposition (CVD), and physical vapor deposition (PVD), ceramic heaters attached to or stored in a ceramic substrate is used to heat a substrate. For example, Patent Document (JP 2004-303736) discloses a ceramic heater configured to heat a stage on which a substrate is mounted.

In general, heat generating elements including ceramic are required to have high thermal conductivity and low resistance, and these heat generating elements are manufactured using a single material (SiC, etc.). When a heat generating element includes a single material, there is a limitation in that the amount of change in the volume resistance value of the heat generating element due to an increase in temperature may be too large. For example, when the volume resistance value of a ceramic material decreases due to an increase in temperature, power applied to the heat generating element would need to be increased to satisfy a required amount of heat generation. When high power is continuously supplied to the heat generating element, there is a limitation that a change of the heat generating element over time may be accelerated.

### SUMMARY

Embodiments are directed to a heater stage including an insulating ceramic substrate including a lower substrate and an upper substrate, each of which includes a first ceramic, and a heat generating element located between the lower substrate and the upper substrate and including a second ceramic and a second metal carbide, wherein each of the first ceramic of the insulating ceramic substrate and the second ceramic of the heat generating element includes at least one of a metal nitride and a metal oxide, a content of the second ceramic in the heat generating element is greater than a content of the second metal carbide in the heat generating element, and the heat generating element has a relative density of 95% or more and a volume resistance value of 1.0 Ω·cm or less at room temperature, and a rate of change of the volume resistance value of the heat generating element with an increase in temperature by 100° C. is 0.1 or less.

According to another aspect, there is provided a heater stage including an insulating ceramic substrate including a lower substrate and an upper substrate, each of which includes a first ceramic, and a heat generating element located between the lower substrate and the upper substrate and including a second ceramic and a second metal carbide, wherein each of the first ceramic of the insulating ceramic substrate and the second ceramic of the heat generating element includes AlN or Al₂O₃, a content of the second ceramic in the heat generating element is equal to or greater than 50 wt %, and a content of the second metal carbide in the heat generating element is equal to or greater than 20 wt % and less than 50 wt %, and the heat generating element has a relative density of 95% or more and a volume resistance value of 1.0 Ω·cm or less at room temperature, and a rate of change of the volume resistance value of the heat generating element with an increase in temperature by 100° C. is 0.1 or less.

According to another aspect, there is provided a heater stage including an insulating ceramic substrate including a lower substrate and an upper substrate, each of which includes a first ceramic and a first metal carbide, and a heat generating element located between the lower substrate and the upper substrate and including a second ceramic and a second metal carbide, wherein each of the first ceramic of the insulating ceramic substrate and the second ceramic of the heat generating element includes AlN or Al₂O₃, the first metal carbide and the second metal carbide include any one of Al, Ti, Zn, Y, Zr, Mo, Ta, and W, the heat generating element has a relative density of 95% or more and a volume resistance value of 1.0 Ω·cm or less at room temperature, and a rate of change of the volume resistance value of the heat generating element with an increase in temperature by 100° C. is 0.1 or less, a content of the second ceramic in the heat generating element is equal to or greater than 50 wt %, and a content of the second metal carbide in the heat generating element is equal to or greater than 20 wt % and less than 50 wt %, a content of the first ceramic in the insulating ceramic substrate is equal to or greater than 80 wt %, and a content of the first metal carbide in the insulating ceramic substrate is equal to or less than 15 wt %, a rate of change of volume resistance value of the insulating ceramic substrate with an increase in temperature by 100° C. is 0.1 or less, and each of the upper substrate and the lower substrate is bonded to the heat generating element by a metal adhesive layer that is formed by a sintering process.

### BRIEF DESCRIPTION OF THE DRAWINGS

Features will become apparent to those of skill in the art by describing in detail exemplary embodiments with reference to the attached drawings in which:

FIG. 1 is a cross-sectional view showing a heater stage according to an embodiment; and

FIG. 2 is a cross-sectional view showing a heater stage according to another embodiment.

### DETAILED DESCRIPTION

Hereinafter, embodiments are described in detail with reference to the accompanying drawings. The same reference numerals are given to the same elements in the drawings, and repeated descriptions thereof are not repeated.

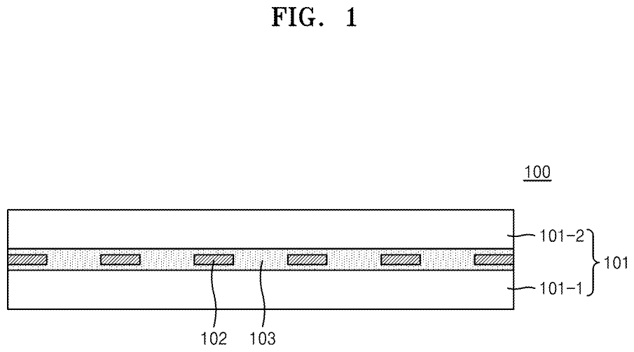

FIG. 1 is a cross-sectional view showing a heater stage 100 according to an embodiment.

Referring to FIG. 1, the heater stage 100 may include an insulating ceramic substrate 101 and a heat generating element 102.

The insulating ceramic substrate 101 may include a lower substrate 101-1 and an upper substrate 101-2, which are vertically stacked on each other. In some embodiments, the lower substrate 101-1 and the upper substrate 101-2 may have the same material composition.

In embodiments, the insulating ceramic substrate 101 may include a ceramic composite material that includes a first ceramic and a first metal carbide. The first ceramic may include a metal oxide and/or a metal nitride. In the first ceramic, the metal oxide may include Al₂O₃ and the metal nitride may include AlN. The first metal carbide may include a metal carbide that contains at least one of Al, Ti, Zn, Y, Zr, Mo, Ta, and W. For example, the first metal carbide may include TiC or ZrC.

In the insulating ceramic substrate 101, a content of the first ceramic may be greater than a content of the first metal carbide. Herein, the term ‘content’ may refer to a volume percent (vol %) or a weight percent (wt %). For example, in the insulating ceramic substrate 101, the weight percent (wt %) of the first ceramic may be greater than the weight percent (wt %) of the first metal carbide. For example, in the insulating ceramic substrate 101, the volume percent (vol %) of the first ceramic may be greater than the volume percent (vol %) of the first metal carbide.

In embodiments, the content of the first ceramic in the insulating ceramic substrate 101 may be equal to or greater than 80 wt %, and the content of the first metal carbide in the insulating ceramic substrate 101 may be equal to or less than 15 wt %. In embodiments, a content of the first ceramic in the insulating ceramic substrate 101 may be about 80 wt % to about 99 wt % and a content of the first metal carbide in the insulating ceramic substrate 101 may be about 1 wt % to about 15 wt %.

In embodiments, the content of the first ceramic in the insulating ceramic substrate 101 may be equal to or greater than 80 vol % and the content of the first metal carbide in the insulating ceramic substrate 101 may be equal to or less than 15 vol %. In embodiments, the content of the first ceramic in the insulating ceramic substrate 101 may be about 80 vol % to about 99 vol % and the content of the first metal carbide in the insulating ceramic substrate 101 may be about 1 vol % to about 15 vol %.

In embodiments, a volume resistance value of the insulating ceramic substrate 101 at room temperature (e.g., 25° C.) may be about 1.0×10¹² Ω·cm to about 1.0×10¹⁸ Ω·cm. Also, a rate of change of the volume resistance value of the insulating ceramic substrate 101 with an increase in temperature by 100° C. in the insulating ceramic substrate 101 may be about 0.1 or less. When the volume resistance value of the insulating ceramic substrate 101 at a first temperature is R1 and the volume resistance value of the insulating ceramic substrate 101 at a second temperature increased by 100° C. from the first temperature is R2,

$$\frac{\vert R 2 - R 1 \vert}{R 1}$$

may be 1/N, where N is a natural number equal to or greater than 10.

The heat generating element 102 may be provided between the lower substrate 101-1 and the upper substrate 101-2. In embodiments, the heat generating element 102 may include a ceramic composite material that includes a second ceramic and a second metal carbide. The second ceramic may include a metal oxide and/or a metal nitride. In the second ceramic, the metal oxide may include Al₂O₃ and the metal nitride may include AlN. The second metal carbide may include a metal carbide that contains at least one of Al, Ti, Zn, Y, Zr, Mo, Ta, and W. For example, the second metal carbide may include TiC or ZrC.

In embodiments, the first ceramic of the insulating ceramic substrate 101 and the second ceramic of the heat generating element 102 may be the same as or different from each other. In embodiments, the first metal carbide of the insulating ceramic substrate 101 and the second metal carbide of the heat generating element 102 may be the same as or different from each other.

In the heat generating element 102, the second ceramic content may be greater than the second metal carbide content. Here, the term ‘content’ may represent a volume percent (vol %) or a weight percent (wt %). For example, in the heat generating element 102, the weight percent (wt %) of the second ceramic may be greater than the weight percent (wt %) of the second metal carbide. For example, in the heat generating element 102, the volume percent (vol %) of the second ceramic may be greater than the volume percent (vol %) of the second metal carbide.

In embodiments, a content of the second ceramic in the heat generating element 102 may be equal to or greater than 50 wt % and a content of the second metal carbide in the heat generating element 102 may be less than 50 wt %. In embodiments, the content of the second ceramic in the heat generating element 102 may be about 50 wt % to about 80 wt %, and the content of the second metal carbide in the heat generating element 102 may be equal to or greater than 20 wt % and less than 50 wt %.

In embodiments, the content of the second ceramic in the heat generating element 102 may be equal to or greater than 50 vol % and the content of the second metal carbide in the heat generating element 102 may be less than 50 vol %. In embodiments, the content of the second ceramic in the heat generating element 102 may be about 50 vol % to about 80 vol % and the content of the second metal carbide in the heat generating element 102 may be equal to or greater than 20 vol % and less than 50 vol %.

In embodiments, the heat generating element 102 may have a relative density of 95% or more. Also, a volume resistance value of the heat generating element 102 at room temperature (e.g., 25° C.) may be 1.0 Ω·cm or less, and a rate of change of volume resistance value of the heat generating element 102 with an increase in temperature by 100° C. in the heat generating element 102 may be 0.1 or less. When the volume resistance value of the heat generating element 102 at a third temperature is R3 and the volume resistance value of the heat generating element 102 at a fourth temperature increased by 100° C. from the third temperature is R4,

$$\frac{\vert R 4 - R 3 \vert}{R 3}$$

may be 1/M, where M is a natural number equal to or greater than 10.

In embodiments, the heat generating element 102 may be formed from a sintered bulk body.

The insulating ceramic substrate 101 and the heat generating element 102 may be bonded and fixed to each other by an adhesive layer 103. That is, the adhesive layer 103 may bond and fix the heat generating element 102 to the lower substrate 101-1 and bond and fix the heat generating element 102 to the upper substrate 101-2.

In embodiments, the adhesive layer 103 may include an inorganic adhesive or a resin adhesive.

In embodiments, the adhesive layer 103 may include a metal adhesive layer that contains metal. The adhesive layer 103 may include a metal adhesive layer that is formed by a sintering process or a re-sintering process. The re-sintering process may include performing a secondary sintering process on a material for which a primary sintering process has been completed. The adhesive layer 103 may include a metal element contained in the insulating ceramic substrate 101 and/or a metal element contained in the heat generating element 102.

In embodiments, the adhesive layer 103 may be formed by a re-sintering phenomenon using powder contained in a thin film located between the lower substrate 101-1 and the upper substrate 101-2. The powder of the thin film may include the same material as the material included in the insulating ceramic substrate 101, for example, Al₂O₃ or AlN. Also, the heat generating element 102 and the insulating ceramic substrate 101 may be bonded to each other by a re-sintering phenomenon that occurs at an interface between the heat generating element 102 and the insulating ceramic substrate 101 due to heat treatment accompanying sintering of a ceramic composite material film. In embodiments, after bonding, the adhesive layer 103 may have a thickness of 500 μm or less. The thickness of the adhesive layer 103 may correspond to a distance between the lower substrate 101-1 and the upper substrate 101-2.

Hereinafter, materials, bonding methods, and evaluation results for components according to embodiments are described.

### Example 1

<Materials>
Insulating ceramic substrate 101: AlN ceramic
Heat generating element 102: Ceramic composite material containing AlN and TiC
Adhesive layer 103: Inorganic adhesive

<Bonding Method and Evaluation Results>

First, each of an insulating ceramic substrate 101 and a heat generating element 102 were manufactured using a known ceramic sintering method.

Next, the insulating ceramic substrate 101 and the heat generating element 102 were machined so that the insulating ceramic substrate 101 and the heat generating element 102 have desired shapes.

Then, an adhesive was applied in a uniform thickness onto each surface of a lower substrate 101-1, a surface of an upper substrate 101-2, and a surface of the heat generating element 102.

Subsequently, the heat generating element 102 was placed between the lower substrate 101-1 and the upper substrate 101-2. By using the adhesive, the heat generating element 102 was aligned and attached to the lower substrate 101-1 and the upper substrate 101-2.

Next, the insulating ceramic substrate 101 and the heat generating element 102 bonded to each other were placed in a thermostat and dried at room temperature (e.g., 25° C.) for 12 hours. After drying, a curing treatment was performed thereon at 60° C. for 5 hours and at 110° C. for 10 hours.

During the curing treatment, a load was applied to bonded surfaces between the insulating ceramic substrate 101 and the heat generating element 102 such that pressure of approximately 6 kPa was applied to these bonded surfaces. Accordingly, a thickness of the adhesive layer 103 was controlled and adhesion therebetween was improved.

Next, a primary defect inspection was performed on the adhesive layer 103 using an ultrasonic probing device. In the primary defect inspection of the adhesive layer 103 using the ultrasonic probing device, whether defects (e.g., voids) occurred in the adhesive layer 103 was checked. During the primary defect inspection for the adhesive layer 103, the size and density of the voids generated in the adhesive layer 103 were compared with reference values to determine whether the adhesive layer 103 passed or did not pass.

Next, a power feeding terminal was mounted to the heat generating element 102 of a heater stage 100 in which the adhesive had been cured.

Subsequently, a heating evaluation operation of monitoring the temperature and electric current value of a wafer while heating the wafer by applying power to the heat generating element 102 was performed.

During the heating evaluation operation, the wafer was mounted on the heater stage 100 and the temperature of the wafer was measured by applying a voltage of 200 V to the heat generating element 102. As a result of the measurement of wafer temperature, it was confirmed that the in-plane temperature uniformity of the wafer was 10% or less when the temperature of the wafer was 500° C.

Also, during the heating evaluation operation, the electric current value for the heat generating element 102 was monitored while the temperature of the wafer changed from room temperature (e.g., 25° C.) to 500° C. As a result of the monitoring, it was confirmed that the electric current value measured in the heat generating element 102 changed (increased) by 6 times.

After the heating evaluation operation, a secondary defect inspection was further performed on the adhesive layer 103 using the ultrasonic probing device, and it was checked whether the state of the adhesive layer 103 was the same as the state during the primary defect inspection. The pass criteria during the secondary defect inspection for the adhesive layer 103 was the same as during the primary defect inspection for the adhesive layer 103.

### Example 2

<Materials>

Insulating ceramic substrate 101: Al₂O₃ ceramic
Heat generating element 102: Thin film containing Al₂O₃ and TiC
Adhesive layer 103: Metal adhesive layer formed through re-sintering by both Al₂O₃ in the insulating ceramic substrate 101 and Al₂O₃ in the heat generating element 102

<Bonding Method and Evaluation Results>

An insulating ceramic substrate 101 was manufactured using a known ceramic sintering method.

The insulating ceramic substrate 101 was machined into a desired shape.

In order to form a heat generating element 102, a paste was prepared by mixing Al₂O₃ powder, TiC powder, and resin. The paste was applied to a lower substrate 101-1 of the insulating ceramic substrate 101. A preliminary heat generating element layer was formed to have a predetermined shape by applying the paste on the surface of the lower substrate 101-1 through a screen printing method.

Next, the preliminary heat generating element layer was dried at 90° C. under a vacuum condition. Then, a preliminary adhesive layer was formed by applying, through a screen printing method, a paste in which Al₂O₃ and resin were mixed onto the lower substrate 101-1 that had been printed with the preliminary heat generating element layer.

Subsequently, a drying treatment was performed thereon at 200° C. under a vacuum condition for 10 hours.

The lower substrate 101-1, which had been printed with the preliminary heat generating element layer and the preliminary adhesive layer, and an upper substrate 101-2 were aligned and attached to each other and then heat-treated for 2 hours at 1500° C. and 5 MPa using hot press equipment. Through the heat treatment, the preliminary heat generating element layer became the heat generating element 102, and the preliminary adhesive layer became the adhesive layer 103. The heat generating element 102 was fixed between the lower substrate 101-1 and the upper substrate 101-2 by the adhesive layer 103.

Next, a structure including the insulating ceramic substrate 101 and the heat generating element 102 was machined into a desired shape.

Next, evaluation was performed in substantially the same manner as described above with reference to Example 1. Specifically, the evaluation included an operation of performing a primary defect inspection on the adhesive layer 103 using an ultrasonic probing device, an operation of mounting a power feeding terminal to the heat generating element 102 in a heater stage 100, a heating evaluation operation of monitoring a temperature of a wafer and an electric current value of the heat generating element 102 while heating the wafer by applying power to the heat generating element 102, and an operation of performing a secondary defect inspection on the adhesive layer 103 using the ultrasonic probing device after the heating evaluation operation. Here, the above operations were sequentially performed.

In the heating evaluation operation, it was confirmed that in-plane temperature uniformity of the wafer was 5% or less when the temperature of the wafer was 500° C. In the heating evaluation operation, it was confirmed that the electric current value measured in the heat generating element 102 changed (increased) by 8 times while the temperature of the wafer changed from room temperature (e.g., 25° C.) to 500° C.

### Example 3

<Materials>
Insulating ceramic substrate 101: AlN ceramic
Heat generating element 102: Ceramic composite material containing AlN and TiC
Adhesive layer 103: Metal adhesive layer formed through re-sintering by both AlN in the insulating ceramic substrate 101 and AlN in the heat generating element 102

<Bonding Method and Evaluation Results>

Each of an insulating ceramic substrate 101 and a heat generating element 102 was manufactured using a known ceramic sintering method.

Next, the insulating ceramic substrate 101 and the heat generating element 102 were machined so that the insulating ceramic substrate 101 and the heat generating element 102 had desired shapes.

Then, a paste in which AlN powder and resin were mixed was prepared.

Then, the paste was applied onto each of a surface of a lower substrate 101-1, a surface of an upper substrate 101-2, and a surface of the heat generating element 102. The paste was applied by a screen-printing method. Then, drying treatment was performed at 200° C. under a vacuum condition for 10 hours on the lower substrate 101-1, the upper substrate 101-2, and the heat generating element 102. which were coated with the paste.

Subsequently, the insulating ceramic substrate 101 and the heat generating element 102 were aligned and attached to each other and then heat-treated for 3 hours at 1800° C. and 10 MPa using hot press equipment.

Next, a structure including the insulating ceramic substrate 101 and the heat generating element 102 was machined into a desired shape.

Next, an evaluation was performed in substantially the same manner as described above with reference to Example 1. Specifically, the evaluation included an operation of performing a primary defect inspection on the adhesive layer 103 using an ultrasonic probing device, an operation of mounting a power feeding terminal to the heat generating element 102 in a heater stage 100, a heating evaluation operation of monitoring a temperature of a wafer and an electric current value of the heat generating element 102 while heating the wafer by applying power to the heat generating element 102, and an operation of performing a secondary defect inspection on the adhesive layer 103 using the ultrasonic probing device after the heating evaluation operation. Here, the above operations were sequentially performed.

In the heating evaluation operation, it was confirmed that in-plane temperature uniformity of the wafer was 10% or less when the temperature of the wafer was 500° C.

In the heating evaluation operation, it was confirmed that the electric current value measured in the heat generating element 102 changed (increases) by 6 times while the temperature of the wafer changed from room temperature (e.g., 25° C.) to 500° C.

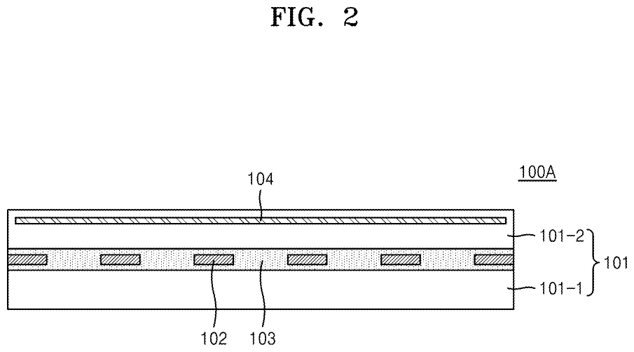

FIG. 2 is a cross-sectional view showing a heater stage 100A according to an embodiment.

Referring to FIG. 2, the heater stage 100A may include an insulating ceramic substrate 101, a heat generating element 102, and an electrostatic chuck electrode 104. The electrostatic chuck electrode 104 may be referred to as an adsorption electrode. The electrostatic chuck electrode 104 may be buried in one of a lower substrate 101-1 and an upper substrate 101-2, for example, the upper substrate 101-2. The electrostatic chuck electrode 104 may receive power from the outside and may be configured to generate an electrostatic force for fixing a wafer.

Hereinafter, materials, bonding methods, and evaluation results for components according to embodiments are described.

### Example 4

<Materials>
Insulating ceramic substrate 101: Al₂O₃ ceramic
Heat generating element 102: Thin film containing Al₂O₃ and TiC
Adhesive layer 103: Metal adhesive layer formed through re-sintering by both Al₂O₃ in the insulating ceramic substrate 101 and Al₂O₃ in the heat generating element 102

<Bonding Method and Evaluation Results>

An electrostatic chuck electrode 104 was buried by employing a known method.

An insulating ceramic substrate 101 and a heat generating element 102 were bonded to each other in substantially the same manner as described above with reference to Example 2 or Example 3.

An upper substrate 101-2, in which the electrostatic chuck electrode 104 was buried, and a lower substrate 101-1 were machined so that the upper substrate 101-2 and the lower substrate 101-1 had desired shapes.

Next, an evaluation was performed in substantially the same manner as described above with reference to Example 2. Specifically, the evaluation included an operation of performing a primary defect inspection on the adhesive layer 103 using an ultrasonic probing device, an operation of mounting a power feeding terminal to the heat generating element 102 in a heater stage 100A, a heating evaluation operation of monitoring a temperature of a wafer and an electric current value of the heat generating element 102 while heating the wafer by applying power to the heat generating element 102, and an operation of performing a secondary defect inspection on the adhesive layer 103 using the ultrasonic probing device after the heating evaluation operation. Here, the above operations were sequentially performed.

In the heating evaluation operation, it was confirmed that in-plane temperature uniformity of the wafer was 6% or less when the temperature of the wafer mounted on the heater stage 100A and electrostatically adsorbed and fixed by the electrostatic chuck electrode 104 was 500° C.

In the heating evaluation operation, it was confirmed that the electric current value measured in the heat generating element 102 changed (increased) by 6 times while the temperature of the wafer changed from room temperature (e.g., 25° C.) to 500° C.

In the heating evaluation operation, it was confirmed that the electric current value of the electrostatic chuck electrode 104 changed (increased) by 80 times while the temperature of the wafer changed from room temperature (e.g., 25° C.) to 500° C.

### Example 5

<Materials>
Insulating ceramic substrate 101: Ceramic containing Al₂O₃ and TiC
Heat generating element 102: Thin film containing Al₂O₃ and TiC
Adhesive layer 103: Metal adhesive layer formed through a re-sintering phenomenon by both Al₂O₃ in the insulating ceramic substrate 101 and Al₂O₃ in the heat generating element 102

An electrostatic chuck electrode 104 was buried in an upper substrate 101-2 of the insulating ceramic substrate 101 as in Example 4.

<Bonding Method and Evaluation Results>

In order to maintain insulating properties, TiC contained in the insulating ceramic substrate 101 was oxidized at a certain temperature before use.

The electrostatic chuck electrode 104 was buried by employing a known method.

A lower substrate 101-1, the upper substrate 101-2, and the heat generating element 102 were bonded to each other by a re-sintering process. A structure that included the insulating ceramic substrate 101 and the heat generating element 102 bonded to each other by the re-sintering process, was machined into a desired shape.

Next, an evaluation was performed in substantially the same manner as described above with reference to Example 2. Specifically, the evaluation included an operation of performing a primary defect inspection on the adhesive layer 103 using an ultrasonic probing device, an operation of mounting a power feeding terminal to the heat generating element 102 in a heater stage 100A, a heating evaluation operation of monitoring a temperature and an electric current value of a wafer while heating the wafer by applying power to the heat generating element 102, and an operation of performing a secondary defect inspection on the adhesive layer 103 using the ultrasonic probing device after the heating evaluation operation. Here, the above operations were sequentially performed.

In the heating evaluation operation, it was confirmed that in-plane temperature uniformity of the wafer was 6% or less when the temperature of the wafer mounted on the heater stage 100A and electrostatically adsorbed and fixed by the electrostatic chuck electrode 104 was 500° C.

In the heating evaluation operation, it was confirmed that the electric current value changed (increased) by 6 times while the temperature of the wafer changed from room temperature (e.g., 25° C.) to 500° C.

In the heating evaluation operation, it was confirmed that the electric current value of the electrostatic chuck electrode 104 changed (increased) by 80 times while the temperature of the wafer changed from room temperature (e.g., 25° C.) to 500° C.

In the heater stage according to embodiments, the heat generating element may include a material with little change in resistance according to temperature. Accordingly, it is possible to reduce the amount of change in resistance of the heat generating element according to a change in temperature of the heat generating element itself and to reduce variability of the electric current flowing through the heat generating element according to the change in temperature. In addition, it is also possible to reduce the need for adjustment work to adjust performance differences between heater stages. Accordingly, the reliability of the heater stage may be improved.

In the heater stage according to embodiments, the adhesive layer for bonding the insulating ceramic substrate to the heat generating element is formed using the re-sintering process. Accordingly, it is possible to improve the heat transfer efficiency in the heater stage and also to enhance the heating efficiency for the substrate mounted on the heater stage.

In the heater stage according to embodiments, the electrostatic chuck electrode is buried in the insulating ceramic substrate. Accordingly, it is possible to utilize the heater stage as an electrostatic chuck device.

In the heater stage according to embodiments, some components include the same material. Accordingly, it is possible to reduce the thermal stress caused by a difference in coefficient of thermal expansion.

In the heater stage according to embodiments, the insulating ceramic substrate and/or the heat generating element contain the metal carbide. Accordingly, it is possible to suppress temperature dependence of electrical resistance values to a low level.

The technical ideas are not limited to the embodiments described above and may be appropriately changed within a scope that does not depart from the embodiments. For example, the heater stage may include an insulating ceramic substrate that includes three or more ceramic bodies vertically stacked on each other and heat generating elements that are arranged between adjacent ceramic bodies.

While embodiments been particularly shown and described with reference to embodiments thereof, it is to be understood that various changes in form and details may be made therein without departing from the spirit and scope of the following claims.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the invention as set forth in the following claims.

What is claimed is:

1. A heater stage comprising:
an insulating ceramic substrate including a lower substrate and an upper substrate, each of which includes a first ceramic; and
a heat generating element located between the lower substrate and the upper substrate and including a second ceramic and a second metal carbide,
wherein each of the first ceramic of the insulating ceramic substrate and the second ceramic of the heat generating element includes at least one of a metal nitride and a metal oxide,
a content of the second ceramic in the heat generating element is greater than a content of the second metal carbide in the heat generating element, and
the heat generating element has a relative density of 95% or more and a volume resistance value of 1.0 Ω·cm or less at room temperature, and a rate of change of the volume resistance value of the heat generating element with an increase in temperature by 100° C. is 0.1 or less.

2. The heater stage as claimed in claim 1, wherein the content of the second ceramic in the heat generating element is equal to or greater than 50 wt %, and
the content of the second metal carbide in the heat generating element is equal to or greater than 20 wt % and less than 50 wt %.

3. The heater stage as claimed in claim 1, wherein the metal nitride includes AlN, and the metal oxide includes Al₂O₃.

4. The heater stage as claimed in claim 1, wherein the second metal carbide includes any one of Al, Ti, Zn, Y, Zr, Mo, Ta, and W.

5. The heater stage as claimed in claim 1, wherein the heat generating element is fixed to each of the lower substrate and the upper substrate by an inorganic adhesive or a resin adhesive.

6. The heater stage as claimed in claim 1, wherein the heat generating element is fixed to each of the lower substrate and the upper substrate by a metal adhesive layer that is formed by a sintering process.

7. The heater stage as claimed in claim 6, wherein the metal adhesive layer has a thickness of 500 μm or less.

8. The heater stage as claimed in claim 1, wherein each of the lower substrate and the upper substrate further includes a first metal carbide, and
a content of the first ceramic in the insulating ceramic substrate is greater than a content of the first metal carbide in the insulating ceramic substrate.

9. The heater stage as claimed in claim 8, wherein the content of the first ceramic in the insulating ceramic substrate is equal to or greater than 80 wt %, and
the content of the first metal carbide in the insulating ceramic substrate is equal to or less than 15 wt %.

10. The heater stage as claimed in claim 9, wherein a rate of change of volume resistance value of the insulating ceramic substrate with an increase in temperature by 100° C. is 0.1 or less.

11. The heater stage as claimed in claim 9, wherein the first metal carbide includes any one of Al, Ti, Zn, Y, Zr, Mo, Ta, and W.

12. The heater stage as claimed in claim 9, wherein the first ceramic and the second ceramic include the same material, and
the first metal carbide and the second metal carbide include the same material.

13. The heater stage as claimed in claim 1, wherein the lower substrate and the upper substrate have the same material composition.

14. The heater stage as claimed in claim 1, further including an electrostatic chuck electrode that is buried in the insulating ceramic substrate.

15. A heater stage comprising:
an insulating ceramic substrate including a lower substrate and an upper substrate, each of which includes a first ceramic; and
a heat generating element located between the lower substrate and the upper substrate and including a second ceramic and a second metal carbide,
wherein each of the first ceramic of the insulating ceramic substrate and the second ceramic of the heat generating element includes MN or Al₂O₃,
a content of the second ceramic in the heat generating element is equal to or greater than 50 wt %, and a content of the second metal carbide in the heat generating element is equal to or greater than 20 wt % and less than 50 wt %, and
the heat generating element has a relative density of 95% or more and a volume resistance value of 1.0 Ω·cm or less at room temperature, and a rate of change of the volume resistance value of the heat generating element with an increase in temperature by 100° C. is 0.1 or less.

16. The heater stage as claimed in claim 15, wherein the insulating ceramic substrate further includes a first metal carbide,
a content of the first ceramic in the insulating ceramic substrate is equal to or greater than 80 wt %, and
a content of the first metal carbide in the insulating ceramic substrate is equal to or less than 15 wt %, and
wherein a rate of change of volume resistance value of the insulating ceramic substrate with an increase in temperature by 100° C. is 0.1 or less.

17. The heater stage as claimed in claim 16, wherein the lower substrate and the upper substrate have the same material composition,
the first ceramic and the second ceramic include the same material, and
the first metal carbide and the second metal carbide include the same metal.

18. The heater stage as claimed in claim 15, wherein each of the upper substrate and the lower substrate is bonded to the heat generating element by an inorganic adhesive or resin adhesive or by a metal adhesive layer that is formed by a sintering process.

19. The heater stage as claimed in claim 15, further including an electrostatic chuck electrode that is buried in the upper substrate.

20. A heater stage comprising:
an insulating ceramic substrate including a lower substrate and an upper substrate, each of which includes a first ceramic and a first metal carbide; and
a heat generating element located between the lower substrate and the upper substrate and including a second ceramic and a second metal carbide,
wherein each of the first ceramic of the insulating ceramic substrate and the second ceramic of the heat generating element includes MN or Al₂O₃,
the first metal carbide and the second metal carbide include any one of Al, Ti, Zn, Y, Zr, Mo, Ta, and W,
the heat generating element has a relative density of 95% or more and a volume resistance value of 1.0 Ω·cm or less at room temperature, and a rate of change of the volume resistance value of the heat generating element with an increase in temperature by 100° C. is 0.1 or less,
a content of the second ceramic in the heat generating element is equal to or greater than 50 wt %, and a content of the second metal carbide in the heat generating element is equal to or greater than 20 wt % and less than 50 wt %,
a content of the first ceramic in the insulating ceramic substrate is equal to or greater than 80 wt %, and a content of the first metal carbide in the insulating ceramic substrate is equal to or less than 15 wt %,
a rate of change of volume resistance value of the insulating ceramic substrate with an increase in temperature by 100° C. is 0.1 or less, and
each of the upper substrate and the lower substrate is bonded to the heat generating element by a metal adhesive layer that is formed by a sintering process.
